(19) United States
(12) Patent Application Publication
(10) Pub. No.: US 2015/0371914 A1
(43) Pub. Date: Dec. 24, 2015

(54) SUBSTRATE PROCESSING APPARATUS AND METHOD OF MANUFACTURING SEMICONDUCTOR DEVICE

(71) Applicant: Hitachi-Kokusai Electric Inc., Tokyo (JP)

(72) Inventors: Yukio OZAKI, Toyama (JP); Reizo NUNOZAWA, Toyama (JP); Satoru TAKAHATA, Toyama (JP)

(21) Appl. No.: 14/842,242

(22) Filed: Sep. 1, 2015

Related U.S. Application Data
(62) Division of application No. 12/537,455, filed on Aug. 7, 2009.

(30) Foreign Application Priority Data
Aug. 22, 2008 (JP) 2008-214678
Jun. 5, 2009 (JP) 2009-135656

(51) Int. Cl. H01L 21/66; G05B 19/418

(52) U.S. Cl. CPC H01L 22/34; H01L 22/26; G05B 19/418; G05B 2219/45031

(57) ABSTRACT

A substrate processing apparatus for executing a predetermined process on a substrate loaded into a process chamber by running a recipe containing a plurality of steps is provided. The recipe includes a processing step of processing the substrate, and a leak check step executed before the processing step to check whether a leak occurs inside the process chamber, and the substrate processing apparatus includes a main control unit configured to execute the processing step while keeping an error that occurs in the leak check step.

### CROSS-REFERENCE TO RELATED PATENT APPLICATION

The present application is a divisional of U.S. patent application Ser. No. 12/537,455, filed Aug. 7, 2009; which claims priority under 35 U.S.C. §119 of Japanese Patent Application No. 2008-214678, filed on Aug. 22, 2008 and Japanese Application No. 2009-135656, filed Jun. 5, 2009, in the Japanese Patent Office, the entire contents of which are hereby incorporated by reference.

### BACKGROUND OF THE INVENTION

1. Field of the Invention

The present invention relates to a substrate processing apparatus and a method of manufacturing a semiconductor device, and more particularly, to an error process.

2. Description of the Prior Art

Generally, the recipe used in the substrate processing apparatus includes a check process that checks whether the substrate processing can be normally performed at the prior stage of substrate processing step. Only when the check is good in the check process, the substrate processing is executed. In addition, the recipe is run by the operation of an operating device connected to the substrate processing apparatus.

FIG. 10 shows an example of a sequence of a conventional process recipe including the check process. The sequence contains a plurality of consecutive steps of a start step (Start), a boat load step (Boat Load), a leak check step (Leak Check), a processing step (Process), a ventilation step (VENT), a purge step (Purge), a boat unload step (Boat Unload), and an end step (END).

In the boat load step, a substrate is charged into a boat by a substrate transfer device. Then, the boat is loaded into a furnace by the upward movement of a boat elevator. In the boat load step, the operation of the substrate transfer device and the operation of the boat elevator can be checked. In the leak check step, whether a pressure depressurized by a vacuum pump of the process furnace corresponds to a target pressure (base arrival pressure) is checked, and whether the leak occurs in the process furnace is checked. When the pressure of the process furnace cannot be depressurized to the target pressure, an alarm is generated and the recipe is abnormally ended.

When it is determined that the leak occurs, the process jumps to a step designated by JUMP command among error processes (HOLD, JUMP, SYSTEM RECIPE) described in a leak check table.

In this case, the jump location is the end step or the depressurization processing step of the leak check step.

When a pressure of the inside of the process furnace cannot be depressurized to the target pressure, and when the leak cannot be recovered even by an error recovery process, maintenance is performed by manual to recover the error. When no error occurs in each step before the processing step, the substrate processing is performed in the processing step. Next, in the ventilation step (VENT), a process gas used in the substrate processing is exhausted. In the purge step, for example, N₂ gas is supplied from an N₂ gas supply source connected to the process furnace, and the atmosphere inside the process furnace is purged. In the boat unload step, the boat is unloaded from the process furnace by the downward movement of the boat, and the substrate is discharged from the boat by the substrate transfer device.

However, in some cases, if the leak occurs but the amount of leak is small, the state inside the process furnace is not deteriorated at a time, and the substrate processing is not affected. In those cases, there are needs to continue the process or the substrate processing, without stopping the recipe.

### SUMMARY OF THE INVENTION

To solve the above problems, an object of the present invention is to provide a substrate processing apparatus and a method of manufacturing a semiconductor device, which are capable of continuing the process without stopping a recipe when an error is caused by a small amount of leak and so on. For example, when the error is caused by a small amount of leak and so on, the process is completed while keeping the error, and an error cancellation process is performed in a later step. Therefore, there are provided a substrate processing apparatus and a method of manufacturing a semiconductor device, which are capable of suppressing the lot-out of the substrate and inhibiting the execution of a next process until the recovery of the apparatus is confirmed. Furthermore, there are provided a substrate processing apparatus and a method of manufacturing a semiconductor device, which are capable of arbitrarily setting an error cancellation process for executing a next process on an operation screen.

According to an aspect of the present invention, there is provided a substrate processing apparatus comprising a main control unit performing a predetermined process on a substrate loaded into a process chamber by executing a recipe at least comprising a loading step of loading a boat charged with the substrate into the process chamber, a processing step of processing the substrate, a leak check step executed before the processing step to check whether the process chamber is depressurized to a predetermined pressure and a leak occurs inside the process chamber, and a unloading step of unloading the boat charged with the substrate out of the process chamber, wherein the main control unit terminates the recipe when the predetermined pressure is not reached or when a leak check error affecting the processing step occurs in the leak check step and the main control unit continues with executing the recipe without performing an error process a when a leak check error not affecting the processing step occurs in the leak check step.

According to another aspect of the present invention, there is provided a substrate processing apparatus for executing a predetermined process on a substrate loaded into a process chamber by running a recipe containing a plurality of steps, the substrate processing apparatus characterized in that: the recipe includes a processing step of processing the substrate, and a leak check step executed before the processing step to check whether a leak occurs inside the process chamber; in a case where an error occurs in the leak check step, if the amount of leak occurring in the leak check step is equal to or less than a first regulated threshold value, the processing step is executed without generating an error; if the amount of leak occurring in the leak check step is greater than the first threshold value and is equal to or less than a second threshold value that does not affect a predetermined substrate processing, the processing step is executed while keeping the error; and if the amount of leak occurring in the leak check step is greater than the second threshold value, a process regulated in an alarm condition table as an error process is executed.

According to another aspect of the present invention, there is provided a method of manufacturing a semiconductor device for executing a predetermined process on a substrate loaded into a process chamber by running a recipe containing a plurality of steps, the method characterized in that: the recipe includes a processing step of processing the substrate, and a leak check step executed before the processing step to check whether a leak occurs inside the process chamber; and when an error occurs in the leak check step, the processing step is executed while keeping the error.

### BRIEF DESCRIPTION OF THE DRAWINGS

FIG. 1 is a schematic configuration view of a vertical substrate processing apparatus in accordance with an embodiment of the present invention.

FIG. 2 is a sectional view of the vertical substrate processing apparatus in accordance with the embodiment of the present invention.

FIG. 3 is a schematic configuration view of a vertical substrate process furnace in accordance with an embodiment of the present invention.

FIG. 4 is a block diagram of a controller that controls the substrate processing apparatus.

FIG. 5 is a flowchart showing an example of process contents of a leak check keep conform control when using process contents of a guard function (guard unit) during a leak check, that is, a first alarm condition table.

FIG. 6 shows a sequence of a recipe (process recipe) including an error check process.

FIG. 7 shows the inhibition of start of a next batch process (JOB2) because a batch process (JOB1) is completed while keeping an error, by using the sequence of the recipe (process recipe) including the error check process.

FIG. 8 shows an example of an edit screen of the process recipe.

FIG. 9 shows an example of a display screen of a setting about the leak check and a display of the leak check state.

FIG. 10 shows a sequence of a conventional process recipe including a check process.

### DETAILED DESCRIPTION OF THE PREFERRED EMBODIMENTS

Hereinafter, preferred embodiments of the present invention will be described with reference to the attached drawings.

First, a substrate processing apparatus in accordance with an embodiment of the present invention is configured as a semiconductor manufacturing apparatus that performs a process of manufacturing a semiconductor device (IC). The following explanation will be given on a vertical substrate processing apparatus (hereinafter, simply referred to as a processing apparatus) that performs an oxidation process, a diffusion process, or a chemical vapor deposition (CVD) process on a substrate.

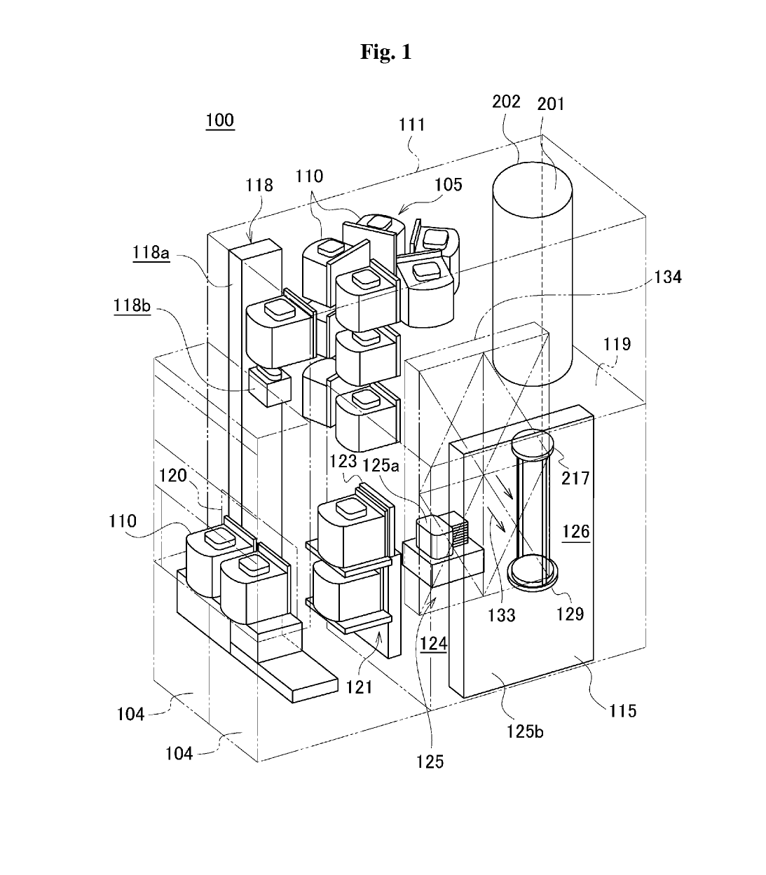

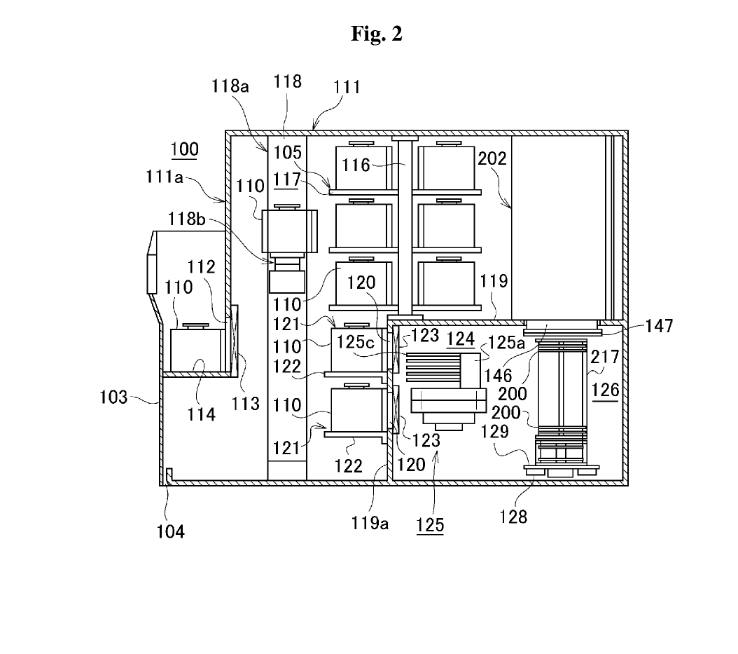

FIG. 1 is a schematic perspective configuration view showing a vertical substrate processing apparatus 100 (hereinafter, also simply referred to as a processing apparatus 100) in accordance with an embodiment of the present invention. Also, FIG. 2 is a sectional view of the vertical processing apparatus 100 in accordance with the embodiment of the present invention.

In the processing apparatus 100, a cassette 110 is used as a wafer carrier of a substrate 200 made of silicon or the like (hereinafter, referred to as a wafer).

Under a front wall 111a of a housing 111 of the processing apparatus 100, a front maintenance opening (not shown) is established as an opening part for maintenance works, and a front maintenance door 104 is installed to open and close the front maintenance opening.

At the front maintenance door 104, a cassette carrying-in and carrying-out opening (substrate container carrying-in and carrying-out opening) 112 is provided in communication with the inside and outside of the housing 111, and the cassette carrying-in and carrying-out opening 112 is designed to be opened and closed by a front shutter (mechanism for opening and closing the substrate container carrying-in and carrying-out opening) 113. At the housing 111 interior of the cassette carrying-in and carrying-out opening 112, a cassette stage (substrate container delivery table) 114 is installed. The cassette 110 is carried onto the cassette stage 114 or carried out from the cassette stage 114 by an intra-process carrying device (not shown).

The cassette stage 114 is put so that the wafers 200 retains a vertical position inside the cassette 110 and a wafer entrance/exit opening of the cassette 110 faces an upward direction, by the intra-process carrying device. The cassette stage 114 is configured so that the cassette 110 is rotated 90 degrees clockwise in a longitudinal direction to backward of the housing 110, and the wafer 200 inside the cassette 110 takes a horizontal position, and the wafer entrance/exit opening of the cassette 110 faces the backward of the housing 111.

At an approximately central lower part of the housing 111 in the front and rear direction, a cassette shelf (substrate container placement shelf) 105 is installed, and the cassette shelf 105 is designed to accommodate a plurality of cassettes 110 in multiple stages and multiple columns. At the cassette shelf 105, a transfer shelf 122 is installed to accommodate the cassettes 110 that are carrying targets of a wafer transfer mechanism 125.

In addition, at the upward of the cassette stage 114, an auxiliary cassette shelf 107 is installed to store the cassette 110 in an auxiliary manner.

A cassette carrying device (substrate container carrying device) 118 is installed between the cassette stage 114 and the cassette shelf 105.

The cassette carrying device 118 is provided with a cassette elevator (substrate container elevating mechanism) 118a that is movable upward and downward while holding the cassette 110, and a cassette carrying mechanism (substrate container carrying mechanism) 118b operating as a carrying mechanism. The cassette carrying device 118 is designed to carry the cassette 110 among the cassette stage 114, the cassette shelf 105 and the auxiliary cassette shelf 107 by the continuous operations of the cassette elevator 118a and the cassette carrying mechanism 118b.

At the rear part of the cassette shelf 105, a wafer transfer mechanism (substrate transfer mechanism) 125 is installed.

The wafer transfer mechanism 125 is provided with a wafer transfer device (substrate transfer device) 125a capable of rotating the wafer 200 in a horizontal direction or moving the wafer 200 straight, and a wafer transfer device elevator (substrate transfer device elevating mechanism) 125b for moving the wafer transfer device 125a upward and downward.

The wafer transfer device elevator 125b is installed at the right end part of the pressure-resistant housing 111.

By the continuous operation of the wafer transfer device elevator 125b and the wafer transfer device 125a, the wafer 200 is charged into and discharged from a boat (substrate holder) 217, with tweezers (substrate holding body) 125c of the wafer transfer device 125a as a placement unit of the wafer 200.

At the upward of the rear part of the housing 111, a process furnace 202 is installed.

The lower end part of the process furnace 202 is configured to be opened and closed by a furnace port shutter (furnace port opening/closing mechanism) 147.

At the downward of the process furnace 202, a boat elevator (substrate holder elevating mechanism) (not shown) is installed as an elevating mechanism that moves the boat 217 upward and downward the process furnace 202, and a seal cap 219 as a lid is horizontally installed in an arm 128 as a connecting tool connected to an elevating table of the boat elevator 115. The seal cap 219 is configured to support the boat 217 vertically and close the lower end part of process furnace 202.

The boat 217 is provided with a plurality of holding members and configured to hold a plurality of sheets (for example, about 50 to about 150 sheets) of wafers 200 horizontally, in such a state they are arranged in a vertical direction, with their centers aligned.

At the upward of the cassette shelf 105, a clean unit 134a configured by a supply fan and a dust-proof filter is installed to supply clean air 133 that is a purified atmosphere, and the clean unit 134a is configured to circulate clean air 133 through the inside of the housing 111.

Moreover, at the left end part of the housing 111 opposite to the wafer transfer device elevator 125b and the boat elevator, a clean unit 134b configured by a supply fan and a dust-proof filter is installed to supply clean air 133.

Clean air 133 brown from the clean unit 134b is circulated through the wafer transfer device 125a and the boat 217, sucked into an exhaust device (not shown) and then exhausted to the outside of the housing 111.

Next, the operation of the processing apparatus 100 in accordance with the present invention will be described with reference to FIG. 1 and FIG. 2.

Before the cassette 110 is supplied to the cassette stage 114, the cassette carrying-in and carrying-out opening 112 is opened by the front shutter 113.

Then, the cassette 110 is carried in from the cassette carrying-in and carrying-out opening 112 and then is placed on the cassette stage 114 so that the wafer 200 takes a horizontal position and the wafer entrance/exit port of the cassette 110 faces in the upward direction. After that, the cassette 110 is rotated by the cassette stage 114 at 90 degrees clockwise in a longitudinal direction, so that the wafer 200 inside the cassette 110 takes a horizontal position and the wafer entrance/exit opening of the cassette 110 faces the backward of the cassette 110.

Then, the cassette 110 is automatically carried and delivered at a specific shelf position of the cassette shelf 105 or the auxiliary cassette shelf 107 by the cassette carrying device 118, and stored temporarily and transferred from the cassette shelf 105 or the auxiliary cassette shelf 107 to the transfer shelf 122 by the cassette carrying device 118, or directly transferred to the transfer shelf 122.

When the cassette 110 is transferred to the transfer shelf 122, the wafer 200 is picked up from the cassette 110 through the wafer entrance/exit opening by the tweezers 125c of the wafer transfer device 125a, and charged into the boat 217 disposed at the backward of the transfer chamber 124.

After delivering the wafer 200 to the boat 217, the wafer transfer device 125a returns to the cassette 110 and charges the next wafer 200 into the boat 217.

When predetermined sheets of the wafers 200 are charged into the boat 217, the lower end part (furnace port) of the process furnace 202, which was kept closed by the furnace port shutter 147, is opened by the furnace port shutter 147. Subsequently, the seal cap 219 is elevated by the elevating arm 128 of the boat elevator, and thus, the boat 217 holding a group of wafers 200 is loaded into the process furnace 202.

After the loading, an arbitrary processing is performed on the wafer 200 in the process furnace 202. After the processing, the wafer 200 and the cassette 110 are carried out from the housing 111 in a reverse order of the above.

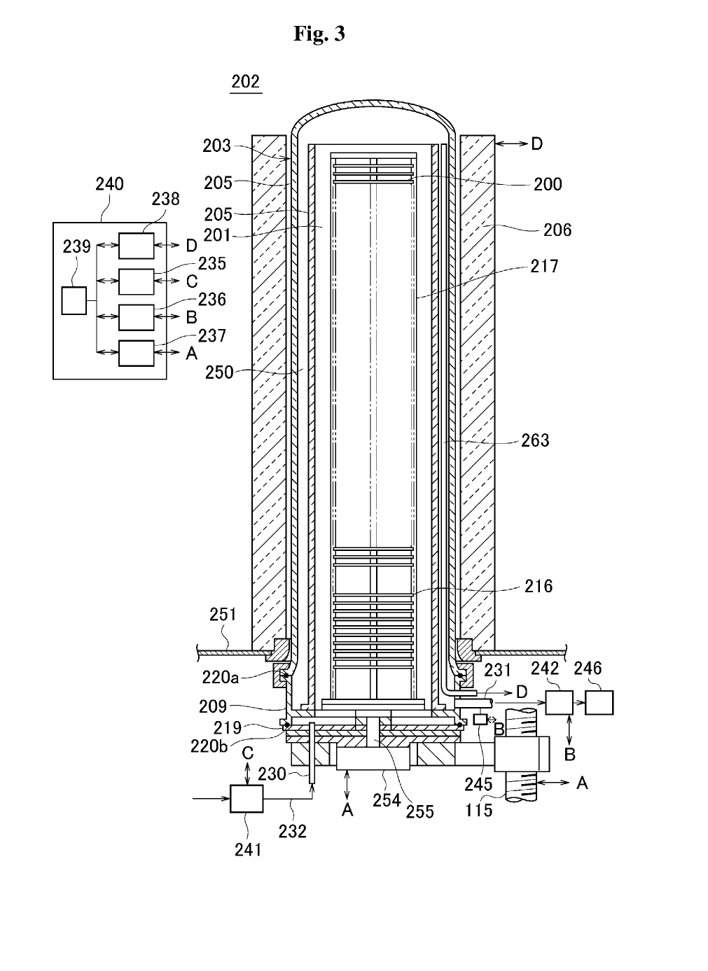

Hereinafter, the schematic configuration of the process furnace 202 of the processing apparatus 100 in accordance with this embodiment will be described with reference to FIG. 3. FIG. 3 is a longitudinal sectional view showing the schematic configuration of the process furnace 202.

As shown in FIG. 3, the process furnace 202 is provided with a heater 206 as a heating mechanism. The heater 206 is cylindrically shaped and is supported on a heater base 251 as a holding plate so that the heater 206 is installed vertically.

At the inside of the heater 206, a process tube 203 as a reaction tube is installed concentrically with the heater 206. The process tube 203 is provided with an inner tube 204 as an inner reaction tube, and an outer tube 205 as an outer reaction tube installed outside the inner tube 204. The inner tube 204 is made of, for example, a heat-resistant material such as quartz (SiO₂) or silicon carbide (SiC), and is formed in a cylindrical shape with opened upper and lower ends. At the cylindrical hollow part of the inner tube 204, a process chamber 201 is formed so that it accommodates wafers 200 as substrates that are arranged at a horizontal position in multiple stages in a vertical direction by a boat 217 as described later. The outer tube 205 is made of, for example, a heat-resistant material such as quartz or silicon carbide, and is formed in a cylindrical shape with a closed upper end and an opened lower end, with its inner diameter greater than that of the inner tube 204. The outer tube 205 is installed concentrically with the inner tube 204.

Under the outer tube 205, a manifold 209 is installed concentrically with the outer tube 205. The manifold 209 is made of, for example, stainless steel or the like and is formed in a cylindrical shape with opened upper and lower ends. The manifold 209 is engaged with the inner tube 204 and the outer tube 205 and is installed to support them. In addition, an O-ring as a seal member is installed between the manifold 209 and the outer tube 205. The manifold 209 is supported on a header base 251, and thus, the process tube 203 is installed vertically. A reaction vessel is configured by the process tube 203 and the manifold 209.

At a seal cap 219, which will be described later, a nozzle 230 as a gas introduction section is connected so that it communicates with the inside of the process chamber 201, and a gas supply pipe 232 is connected to the nozzle 230. At the upstream side, which is opposite to the connection side of the gas supply pipe 232 and the nozzle 230, a process gas supply source (not shown) or an inert gas supply source (not shown) are connected through a mass flow controller (MFC) 241 as a gas flow rate controller. A gas flow rate control unit 235 is electrically connected to the MFC 241 and is configured so that gas is supplied at a desired flow rate at a desired timing.

At the manifold 209, an exhaust pipe 231 is installed to exhaust atmosphere inside the process chamber 201. The exhaust pipe 231 is disposed at the lower end part of the cylindrical space 250 formed by a gap between the inner tube 204 and the outer tube 205, and communicates with the cylindrical space 250. At the downstream side opposite to the connection side of the exhaust pipe 231 and the manifold 209, a vacuum exhaust device 246 such as a vacuum pump is connected through a pressure sensor 245 as a pressure detector and a pressure regulator 242, and is configured to vacuum-exhaust the inside of the process chamber 201 to a certain pressure (vacuum degree). A pressure control unit 236 is electrically connected to the pressure regulator 242 and the pressure sensor 245, and the pressure control unit 236 is configured to control the pressure regulator 242 so that the inside of the process chamber 201 is regulated to a desired pressure at a desired timing, based upon the pressure detected by the pressure sensor 245.

Under the manifold 209, the seal cap 219 is installed as a furnace port lid that air-tightly closes the lower opening of the manifold 209. The seal cap 219 is configured so that it is in contact with the lower end of the manifold 209 from the lower side thereof in a vertical direction. The seal cap 219 is made of, for example, a metal such as stainless steel, and is formed in a disk shape. On the top surface of the seal cap 219, an O-ring 220b is installed as a seal member that is in contact with the lower end of the manifold 209. On the opposite side of the seal cap 219 to the process chamber 201, a rotation mechanism 254 that rotates the boat is installed. A rotation shaft 255 of the rotation mechanism 254 passes through the seal cap 219 and is connected to the boat 217 which will be described later. The rotation mechanism 254 is configured to rotate the boat 217 so that the wafer 200 is rotated.

The seal cap 219 is configured so that it is moved in a vertical direction by a boat elevator 115 as an elevation mechanism installed vertically at the outside of the process tube 203, and thus, the boat 217 can be loaded into or unloaded from the process chamber 201. A drive control unit 237 is electrically connected to the rotation mechanism 254 and the boat elevator 115, and is configured to execute a control so that a desired operation is performed at a desired timing.

The boat 217 as a substrate holder is made of, for example, a heat-resistant material such as quartz or silicon carbide, and is configured to hold a plurality of wafers 200 at a horizontal position in multiple stages, with their centers aligned. In addition, at the lower part of the boat 217, a plurality of disk-shaped heat insulation plates 216 as heat insulation members made of, for example, a heat-resistant material such as quartz or silicon carbide, are arranged at a horizontal position in multiple stages, and are configured to make it difficult to transfer heat from the heater 206 toward the manifold 209.

AT the inside of the process tube 203, a temperature sensor 263 is installed as a temperature detector. A temperature control unit 238 is electrically connected to the heater 206 and the temperature sensor 263, and is configured to control an electrified state of the heater 206 at a desired timing, based upon temperature information detected by the temperature sensor 263, in order that temperature inside the process chamber 201 is made to have a desired temperature distribution.

The gas flow rate control unit 235, the pressure control unit 236, the drive control unit 237, and the temperature control unit 238 also constitute an operation unit and an input/output unit, and are electrically connected to a main control unit 239 that controls the entire substrate processing apparatus. The gas flow rate control unit 235, the pressure control unit 236, the drive control unit 237, the temperature control unit 238, and the main control unit 239 are configured as a control unit 240.

Next, explanation will be given on a method of forming a thin film on a wafer 200 by a CVD process, as one of semiconductor device manufacturing processes, by using the process furnace 202 having the above-described configuration. In addition, in the following description, the operations of the respective elements constituting the processing apparatus 100 are controlled by the control unit 240.

When a plurality of wafers 200 are charged into the boat 217, as shown in FIG. 3, the boat 217 holding the plurality of wafers 200 is lifted by the boat elevator 115 and loaded into the process chamber 201. In this state, the seal cap 219 seals the lower end of the manifold 209 through the O-ring 220.

The inside of the process chamber 201 is vacuum-exhausted to a desired pressure (vacuum degree) by the vacuum exhaust device 246. At this time, the pressure inside the process chamber 201 is measured with the pressure sensor 245, and the pressure regulator 242 is feedback controlled, based upon the measured pressure. In addition, the inside of the process chamber 201 is heated to a desired temperature by the heater 206. At this time, the electrified state of the heater 206 is feedback controlled, based upon temperature information detected by the temperature sensor 263, in order that the inside of the process chamber 201 is made to have a desired temperature distribution. Subsequently, the boat 217 is rotated by the rotation mechanism 254, and therefore, the wafers 200 are rotated.

Then, gas supplied from the process gas supply source and controlled to be a desired flow rate by the MFC 241 circulates through the gas supply pipe 232 and then is introduced from the nozzle 230 into the process chamber 201. The introduced gas rises up inside the process chamber 201 and outflows from the upper end opening of the inner tube 204 toward the cylindrical space 250, and then exhausts through the exhaust pipe 231. The gas contacts the surface of the wafer 200 when passing through the inside of the process chamber 201, and a thin film is deposited on the surface of the wafer 200 by a thermal CVD reaction at this time.

When a predetermined process time passes by, inert gas is supplied from the inert gas supply source, and gas inside the process chamber 201 is replaced with the inert gas. Simultaneously, the inside of the process chamber 201 returns to the normal pressure.

After that, the seal cap 219 is moved downward by the boat elevator 115, and simultaneously, the lower end of the manifold 209 is opened. The boat 217 charged with the processed wafers 200 is unloaded from the lower end of the manifold 20 to the outside of the process tube 203. Then, the processed wafers 200 are discharged from the boat 217.

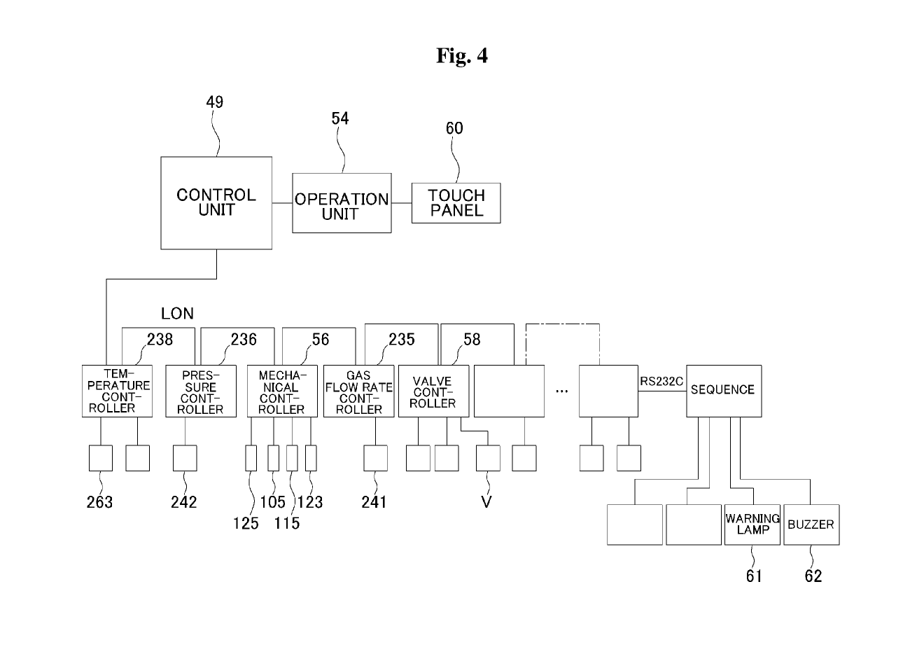

FIG. 4 is a block diagram of the control unit 240 that controls the processing apparatus 100.

In FIG. 4, a gas flow rate controller 235 corresponds to the gas flow rate control unit 235, a pressure controller 236 corresponds to the pressure control unit 236, and a temperature controller 238 corresponds to the temperature control unit 238. A mechanical controller 56 corresponds to the drive control unit 237 and is a controller that controls the carrying system of the wafers 200. A valve controller 58 is a controller that switches the opening and closing of the valve.

Various controllers mounted on the substrate processing apparatus 100, such as the control unit 49, the temperature controller 238, the gas flow rate controller 235, the mechanical controller 56, and the valve controller 58, are mutually connected through, for example, a LON network (hereinafter, referred to as a network) LON.

The wafer transfer mechanism 125, the rotary cassette shelf 105, the cap attaching/detaching mechanism 123, the boat elevator 115 and so on are connected to the mechanical controller 56. The temperature sensor 263 that detects the temperature of the process chamber 201 is connected to the temperature controller 238. The MFC 241 that controls the flow rates of the process gas (oxidation gas, annealing gas, film-forming gas) supplied into the process chamber 201 is connected to the gas flow rate controller 235. The APC (pressure regulator) 242 that controls the pressure of the process chamber 201 is connected to the pressure controller 236. Valves V that opens and closes gas supply pipes (not shown) supplying the process gas, oxygen gas and hydrogen gas into the process chamber 201 are connected to the valve controller 58.

If the LON network is used, the respective controllers of the processing apparatus 100, such as the mechanical controller 56, the temperature controller 238, the gas flow rate controller 235 and the valve controller 58, are connected to the same hierarchy with respect to the network LON, and therefore, there is a merit that they can be replaced or regulated without affecting one another, and interconnections can be simplified. However, instead of the network LON, a general LAN network provided with a hub and a router may also be used.

The main control unit 239 including the control unit 49 and the operation unit 54 is configured as a computer that is provided with an operation control unit (CPU), a storage unit, and a communication control unit. When receiving an instruction of running a recipe from the operation unit 54, the control unit 49 transmits the received instruction of running the recipe through the network LON to the temperature controller 238, the gas flow rate controller 235, the mechanical controller 56, the valve controller 58, and so on. For example, when the control unit 49 receives the instruction of running the recipe from a touch panel 60 by the operator, the control unit 49 transmits the instruction of one of a plurality of steps to the temperature controller 238, the gas flow rate controller 235, the mechanical controller 56, the valve controller 58, and so on with reference to a process recipe to be run. Also, in FIG. 4, while the touch panel 60 used both as the display unit and as the input unit is connected to the operation unit 54, it is apparent that the present invention is not limited to this configuration.

Various functions are mounted on the operation unit 54 by a plurality of programs using computer hardware resources.

In this embodiment, a function of displaying screens such as an operation screen on the touch panel 60, a screen display function of searching a process recipe stored in a fixed storage and displaying the searched process recipe on the screen of the touch pad 60, a file creation/edit function of enabling the creation/edit of the process recipe, a storage function of storing the created/edited process recipe in the fixed storage, a table creation function of creating a variety of tables, a function of continuing the recipe in response to the severity of error when an error occurs in a predetermined step, and a function of enabling an arbitrary setting of an error cancellation process are mounted. In addition, programs necessary for operation, control and screen display of the operation unit 54 and the control unit 49, necessary screen files, and tables are stored in the fixed storage.

In the function of continuing the recipe in response to the severity of error, for example, when the amount of leak occurring in the leak check step is equal to or less than a first regulated threshold value, the processing step is executed without generating an error. In addition, when the amount of leak occurring in the leak check step is greater than the first threshold value and is equal to or less than a second threshold value that does not affect a predetermined substrate processing, the processing step is executed while keeping the error. Moreover, when the amount of leak occurring in the leak check step is greater than the second threshold value, a process regulated in an alarm condition table is executed as an error process.

In addition, the operation unit 54 has a function of displaying an abnormal end and/or notifying the abnormal end to an external device (for example, a host computer and so on) when the error occurs in the leak check step and thus the recipe is ended while keeping the error, or when the amount of leak is greater than the second threshold value. Moreover, in this embodiment, the abnormal end is cancelled by executing the predetermined error cancellation process.

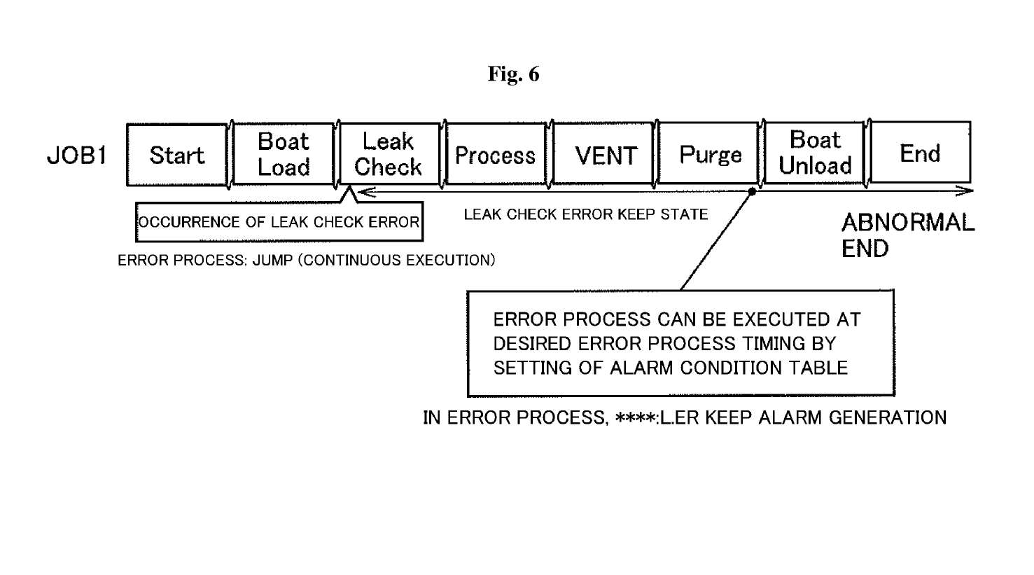

FIG. 6 shows a sequence of a recipe (process recipe) including a leak check process.

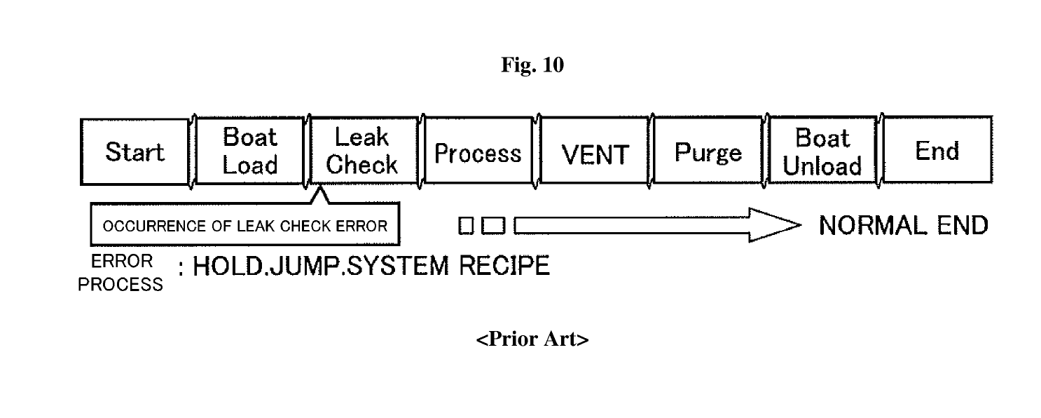

The recipe is run by the operation of an operating device connected to the processing apparatus 100. As described in FIG. 10, the sequence contains a plurality of consecutive steps of a start step (Start), a boat load step (Boat Load), a leak check step (Leak Check), a processing step (Process), a ventilation step (VENT), a purge step (Purge), a boat unload step (Boat Unload), and an end step (END).

In the leak check step, a check about whether to depressurize the process furnace 202 to a target pressure (base arrival pressure) by the vacuum pump, and a check about whether the leak occurs in the process furnace 202 are executed. When the process furnace cannot be depressurized to the target pressure, the recipe is abnormally ended. That is, the process proceeds to the end step, and the apparatus mode changes from “RUN” to “ABNORMAL END”.

When the pressure of the process furnace arrives at the target pressure, the leak state is determined by comparing the pressure of the process furnace with a determination value.

When the amount of leak is larger than the regulated amount, an alarm condition table corresponding to the severity of the leak is referenced among a plurality of alarm condition tables. A command corresponding to the severity of leak is designated to the referenced table, and the operation unit 54 executes the command designated in the alarm condition table.

Herein, two alarm condition tables are taken as an example.

One of the two alarm condition tables is an alarm condition table (hereinafter, referred to as a first alarm condition table) used when no problem arises in the substrate processing even though the process is continued because the amount of leak is slightly larger than the regulated amount, and the other is an alarm condition table (hereinafter, referred to as a second alarm condition table) used when a problem occurs in the substrate processing when the process is continued because the amount of leak is much larger than the regulated amount.

In the first alarm condition table, commands “BUZZER”, “JUMP”, “HOLD” and “SYSTEM RECIPE” in a current batch process, a command for storing contents of error in the fixed storage as a file or storing contents of error in the table as data, and a command for inhibiting a process in a next batch process, including a start, are described.

In the second alarm condition table, “BUZZER”, “JUMP”, “HOLD” and “SYSTEM RECIPE” are described as commands.

The command “SYSTEM RECIPE” is a command that indicates contents of an error recovery process. The command “JUMP” is a command that jumps to a designated location, and the command “HOLD” is a command that holds for a designated time.

For this reason, when the leak check error occurs and the error state is light (no problem arises in the substrate processing), the process continues to be executed by “JUMP” while keeping the error state, that is, without executing the error process. When the recipe is ended, the next batch process is inhibited by changing the apparatus mode from “RUN” to “ABNORMAL END”

Upon maintenance, logging data and contents of error are stored in the fixed storage, for example, a hard disk, and thus, the maintenance is facilitated. Also, in “ABNORMAL END” mode, since an error occurs during the running of the recipe, “ABNORMAL END” is notified.

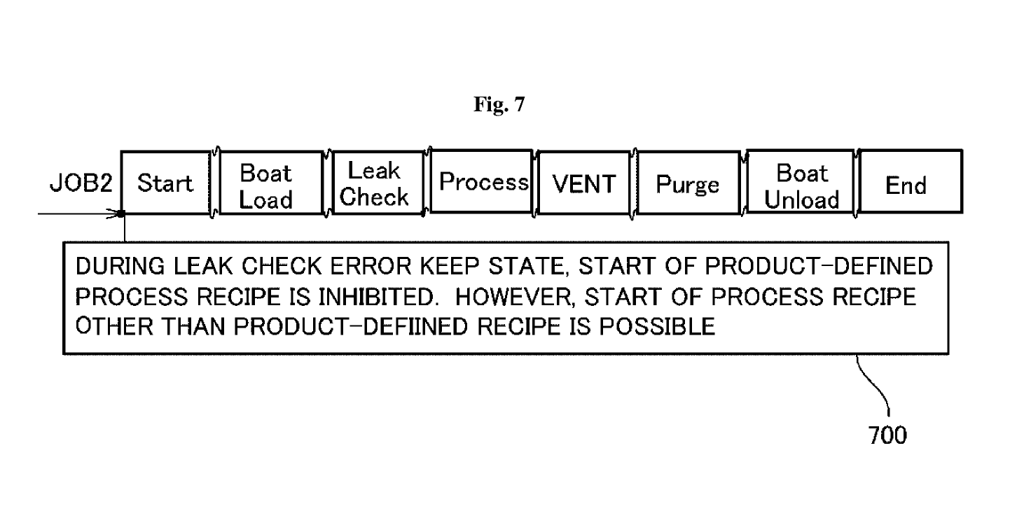

Therefore, JOB2 (see FIG. 7) that is an instruction to process the next batch from the external device (for example, a host computer (not shown)) or the operation unit 54 is not executed. However, as described later, when the abnormal end is cancelled by canceling the leak check error, the next batch can be processed.

In addition, when an error state is so severe that a problem arises in the substrate processing if the process is executed as it is, the process following the leak check is jumped to the end step, and the apparatus mode changes from “RUN” to “ABNORMAL END”, and the error process is executed.

Moreover, when the inside of the process furnace cannot be depressurized to the target pressure, the error is recovered in a manual manner with reference to the logging data.

In addition, the first threshold value (for example, regulated amount) and the second threshold value (for example, the amount of leak at which a problem starts to occur in the substrate) need to be set according to the first alarm condition table and the second alarm condition table, and the threshold values are previously calculated by experiments.

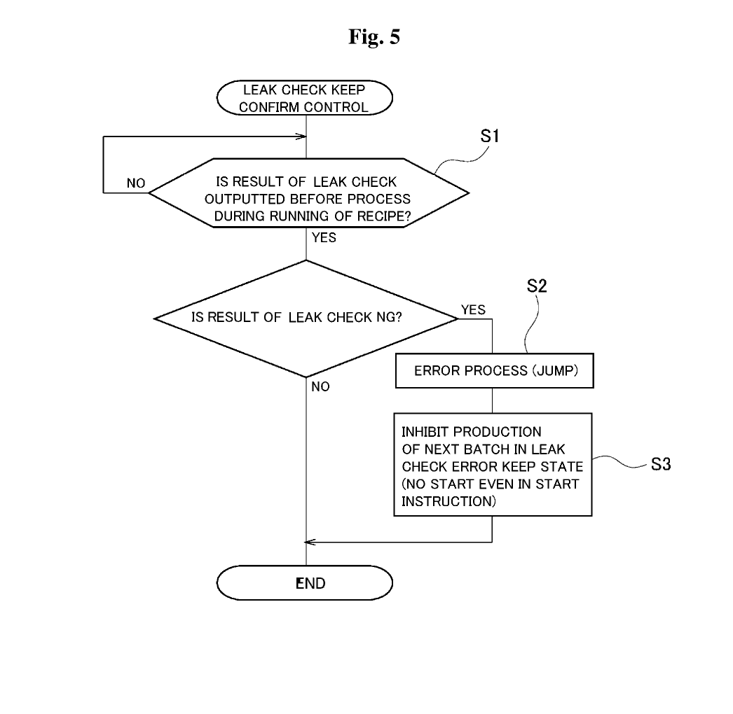

FIG. 5 shows an example of process contents of the leak check keep confirm control when using the contents of the error process during the leak check, that is, when using the first alarm condition table.

In this control, it is determined whether the result of the leak check is outputted before the processing step during the running of the recipe (process recipe) (Step S1). Next, it is determined whether the result of the leak check is NG or not, that is, whether the leak occurs or not. When the result of the leak check is NG, as described above, “JUMP is referenced in the first alarm condition table and then executed. The process proceeds to the next processing step while keeping the error (Step S2). The process is executed based upon the first alarm condition table corresponding to the severity of error, that is, the level of the error, and then, the next batch is inhibited (Step S3).

In addition, when the error state is light, the current batch process can be ended by continuing to execute the process. Hence, it is possible to cope with the needs of the semiconductor device manufacturers.

Regarding FIG. 5, for example, when a severe threshold value is required by a customer, an error may occur even though the leak is at a level at which no problem arises in the substrate processing. At this time, even though any leak check error occurs, the recipe can be ended by continuously executing the process on the substrate while keeping the error. Therefore, no defective products remain in the inside of the furnace. In addition, since the error is kept, the recipe is considered as the abnormal end. Therefore, the next batch is not introduced, and the substrate processing result can be checked before the introduction of the next batch. Consequently, at least the lot-out of the next batch can be prevented.

Such an operation is efficient when executing as an operation just like an operation that is started as soon as the substrate is delivered to the factory. That is, several threshold values are set and the substrate processing is executed with the respective threshold values. Then, by checking the substrate processing results, the leak level limit of the delivered device and the range of the leak amount causing no problem in the substrate processing can be checked.

FIG. 7 shows the inhibition of start of a next batch process (JOB2) because a batch process (JOB1) is completed while keeping an error, by using the sequence of the recipe (process recipe) including the error check process. It is apparent that the present invention is not limited to the case where the contents of the next process recipe to be run are the same as the contents of the process recipe before being ended while keeping the error, but the start of the next batch process is inhibited in the case where they are different from each other.

In addition, when the start button for starting the next batch process while keeping the leak check error is incorrectly pressured, for example, the comment 700 of FIG. 7 may be displayed on the display unit. Moreover, when the process recipe is ended while keeping the error, the comment 700 of FIG. 7 may be always displayed on the display unit, and, for example, when “cancel” button is pressed, the comment 700 may be deleted.

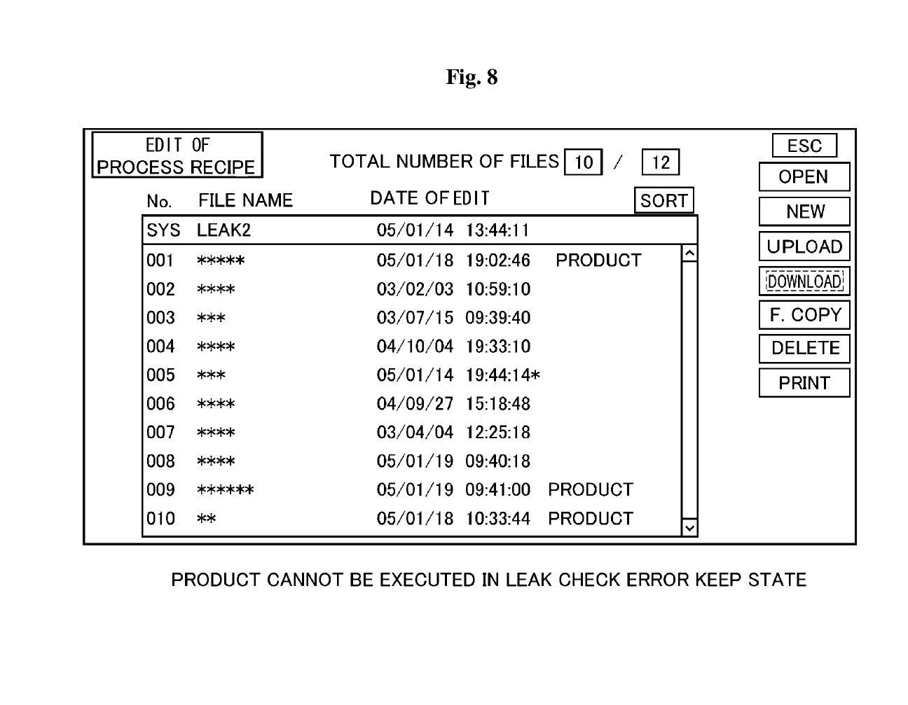

FIG. 8 shows an example of an edit screen (display unit) that edits the process recipe.

On the edit screen of the process recipe, the file name of the recipe, the date of edit, and the kind of the recipe are displayed. On this screen, “PRODUCT” is the product-defined process recipe. In FIG. 8, the process recipe is not run in such a state the leak check error is kept. However, the start is possible in recipes other than the process recipe. Herein, the process recipe is distinctly identified with other recipes. For example, it is preferable that the process recipe is displayed with color classification because the impossibility of the start is further emphasized. In addition, the product-defined process recipe may be configured to delete the description “PRODUCT” when the “cancel” button to be described later is pressed. Moreover, when the color classification exists, the color classification may be removed.

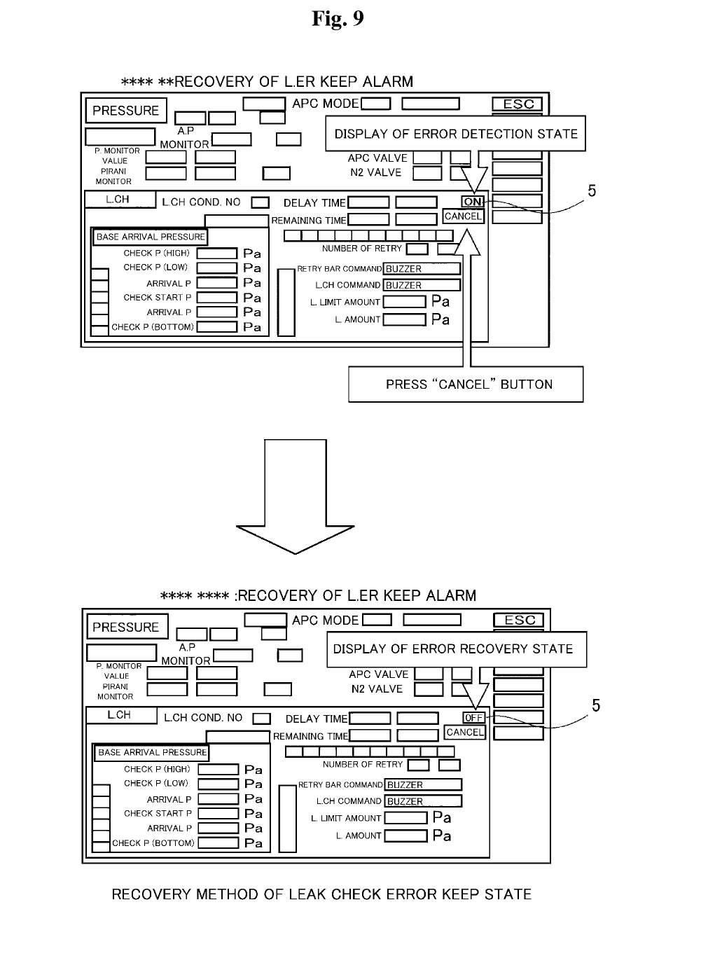

FIG. 9 shows an example of a display screen (display unit) of a setting about the leak check, and a display of the leak check state.

Base arrival pressure, check pressure (HIGH)(LOW), check start pressure, and check pressure (BOTTOM) are displayed as display items of the leak check, and delay time, number of retry, command, leak limit amount, leak amount, and leak error display 5 are displayed. On the leak error display 5, character “ON” is displayed when an error occurs in the leak check, and character “OFF” is displayed when no error occurs. In addition, at a position near the leak error display 5, “CANCEL” button is displayed as a cancellation means that enable the cancellation of the error occurring in the leak check. If the cancel button is pressed when the processing apparatus 100 changes to a maintenance mode, the leak check error keep state is forcibly cancelled (recovered).

Moreover, in this embodiment, while the leak check has been exemplified as the error check, it is apparent that the present invention can be applied to any check using the detection value and the determination value in the substrate processing apparatus 100. Also, while it has been exemplified the case that proceeds to the next processing step by forcibly ending the leak check step by the “JUMP” command, the present invention is not limited thereto.

In, addition, as the error recovery process, the display may be changed automatically without operation of pressing the button (cancel button) on the operation screen. The timing of the error recovery process may be set to a timing (step) designated by the user. In particular, in a case where the substrate processing must be continued even though the error occurs in the leak check, the recipe of the next batch can be continuously run, and thus, it is possible to cope with the needs of the factory side to improve the throughput as highly as possible.

Moreover, in a 2-boat system, when an error occurs, the movement of the boat 217 and the transfer of the wafer 200 may also be inhibited.

In the substrate processing apparatus and the method of manufacturing the semiconductor device according to the present invention, even though an error is caused by a small amount of leak or the like, the substrate processing can be continued without stopping the recipe. For example, regarding the error such as the leak, since the running recipe can be ended till the last in response to the actual amount of leak, the lot-out of the substrate can be suppressed, compared with the stopping of the recipe. At this time, the next process is inhibited. Moreover, since the error cancellation process for executing the next process may be arbitrarily run on the operation screen, it is possible to the user's needs, and the recipe used in the next process can be arbitrarily run. Consequently, it is possible to prevent the lot-out of the substrate used in the next batch process.

(Supplementary Note)

Preferred embodiments of the present invention will be complementarily noted.

According to an embodiment of the present invention, there is provided a substrate processing apparatus for executing a predetermined process on a substrate loaded into a process chamber by running a recipe containing a plurality of steps, the substrate processing apparatus characterized in that: the recipe includes a processing step of processing the substrate, and a leak check step executed before the processing step to check whether a leak occurs inside the process chamber, and the substrate processing apparatus includes a main control unit configured to execute the processing step while keeping an error that occurs in the leak check step.

Preferably, the main control unit is configured not to start a substrate recipe to be processed next, while the error is kept.

Preferably, when an error occurs in the leak check step, the main control unit executes the processing step while keeping the error, and then displays and notifies an abnormal end to the outside.

Preferably, the main control unit executes a process regulated in an alarm condition table as an error process in response to an importance degree of the error.

Preferably, when the amount of leak occurring in the leak check step is equal to or less than a first regulated threshold value, the main control unit executes the processing step without generating an error. When the amount of leak occurring in the leak check step is greater than the first threshold value and is equal to or less than a second threshold value that does not affect a predetermined substrate processing, the main control unit executes the processing step while keeping the error. When the amount of leak occurring in the leak check step is greater than the second threshold value, the main control unit executes a process regulated in an alarm condition table as an error process.

Preferably, the main control unit includes an operation unit that receives an instruction to execute the recipe, and a control unit that executes the recipe according to the received instruction, and the operation unit includes a display unit configured to display a cancel button that cancels the error.

Preferably, while the recipe is running, the cancel button may be configured so that it is not displayed on the display unit, or it is not pressed.

According to another embodiment of the present invention, there is provided a method of manufacturing a semiconductor device for executing a predetermined process on a substrate loaded into a process chamber by running a recipe containing a plurality of steps, the method characterized in that: the recipe comprises a processing step of processing the substrate, and a leak check step executed before the processing step to check whether a leak occurs inside the process chamber, and when an error occurs in the leak check step, the processing step is executed while keeping the error.

According to another embodiment of the present invention, there is provided a method of manufacturing a semiconductor device, including: a boat load step of loading a substrate holder holding a plurality of substrates into a process chamber; a leak check step of checking whether a leak occurs inside the process chamber; a processing step of processing the substrate; and a boat unload step of unloading the substrate holder holding the processed substrate. In the leak check step, the processing step is executed while keeping the error even though the error occurs.

According to another embodiment of the present invention, there is provided a substrate processing apparatus including: an operation unit configured to receive an instruction to execute various recipes containing a plurality of steps; and a control unit configured to execute a control to execute the substrate processing according to the instruction. The recipe includes a leak check step of checking whether the leak occurs in the process furnace, before a step of processing a substrate inside the process furnace. When the error occurs in the leak check step while running the recipe that processes the substrate, the operation unit is configured to continue the recipe in response to severity of the error and simultaneously notify an alarm indicating that the next batch cannot be processed continuously because the error occurs during the running of the recipe upon the end of the recipe.

In this case, upon the occurrence of the error, a next predetermined step may be executed by forcibly ending (jumping) the step where the error occurs.

Also, when the error is kept, the running (processing) of the recipe processing the next substrate is inhibited.

In addition, the operation unit may be provided with a display unit that displays various screens, and the operation unit may control the display unit to display a button that forcibly cancels the error upon maintenance.

According to another embodiment of the present invention, there is provided a substrate processing method that continues a recipe in response to severity of error when an error occurs in a predetermined step, upon the running of a substrate processing step.

What is claimed is:

1. A method of manufacturing a semiconductor device, comprising: executing a process recipe comprising:
(a) performing a leak check step to check whether a leak occurs inside a process chamber;
(b) performing a process step to process a substrate in response to an amount of leakage checked in the leak check step is equal to or less than a first threshold value;
(c) performing the process step while keeping a leak check error in response to the amount of leakage is greater than the first threshold value and equal to or less than a second threshold value without affecting the process step; and
(d) performing an error processing step defined in an alarm condition table in response to the amount of leakage is greater than the second threshold value;
wherein the process recipe is terminated in response to the substrate is processed in the step (b),
wherein the process recipe is abnormally terminated in response to the substrate is processed while keeping the leak check error in the step (b), and
wherein the process recipe is abnormally terminated in response to the error processing step is performed in the step (c).

2. The method of claim 1, wherein an execution of a next process is inhibited in response to the process step is performed while keeping the leak check error.

3. The method of claim 1, wherein an execution of a next process is inhibited and an editing of the process recipe is disabled in response to the process step is terminated while keeping the leak check error.

4. The method of claim 1, wherein a next process and a reason for inhibiting the next process are displayed in response to the process step is terminated while keeping the leak check error.

5. The method of claim 1, further comprising: displaying a cancel button for cancelling the leak check error, wherein an execution of a next process is inhibited until the cancel button is pressed in response to the process step is terminated while keeping the leak check error.

6. The method of claim 5, wherein the cancel button is unable to be pressed during the process step.

7. The method of claim 5, wherein the leak check error is forcibly canceled in response to the cancel button is pressed after terminating the process step.

8. The method of claim 7, wherein a reason for inhibiting a next process is stopped from being displayed in response to the cancel button is pressed.

9. The method of claim 1, further comprising: displaying an edit screen for editing the process recipe, wherein the process recipe and other recipes are distinctly displayed while keeping the leak check error.

10. The method of claim 9, wherein a displayed color difference between the process recipe and other recipes are deleted while keeping the leak check error in response to a cancel button for canceling the leak check error is pressed.

11. The method of claim 1, wherein a process in an alarm condition table is executed according to an importance degree of the error.

12. The method of claim 1, wherein the process recipe comprises:
loading a substrate holder holding a plurality of substrates into the process chamber; and
unloading the substrate holder holding the plurality of substrates.

13. The method of claim 12, further comprising: inhibiting a transfer of a substrate holder used in a next batch or a transfer of substrate in the next batch to the substrate holder.

14. The method of claim 1, wherein further comprising: depressurizing the process chamber to a predetermined pressure, wherein the process recipe is abnormally terminated by proceeding to a last step without performing the process step in response to the process chamber is not depressurized to the predetermined pressure.

15. The method of claim 1, wherein the process step comprises one selected from the group consisting of an oxidation process, a diffusion process and a chemical vapor deposition process.

16. The method of claim 1, wherein the process step comprises a film forming process.

17. A method of controlling a substrate processing apparatus, comprising: executing a process recipe comprising:
(a) performing a leak check step to check whether a leak occurs inside a process chamber;
(b) performing a process step to process a substrate in response to an amount of leakage checked in the leak check step is equal to or less than a first threshold value;
(c) performing the process step while keeping a leak check error in response to the amount of leakage is greater than the first threshold value and equal to or less than a second threshold value without affecting the process step; and
(d) performing an error processing step defined in an alarm condition table in response to the amount of leakage is greater than the second threshold value;
wherein the process recipe is terminated in response to the substrate is processed in the step (b),
wherein the process recipe is abnormally terminated in response to the substrate is processed while keeping the leak check error in the step (b), and
wherein the process recipe is abnormally terminated in response to the error processing step is performed in the step (c).

18. A non-transitory computer-readable recording medium storing a program for causing a substrate processing apparatus to execute a process recipe comprising:
(a) performing a leak check step to check whether a leak occurs inside a process chamber;
(b) performing a process step to process a substrate in response to an amount of leakage checked in the leak check step is equal to or less than a first threshold value;
(c) performing the process step while keeping a leak check error in response to the amount of leakage is greater than the first threshold value and equal to or less than a second threshold value without affecting the process step; and
(d) performing an error processing step defined in an alarm condition table in response to the amount of leakage is greater than the second threshold value;
wherein the process recipe is terminated when the substrate is processed in the step (b),
wherein the process recipe is abnormally terminated when the substrate is processed while keeping the leak check error in the step (b), and
wherein the process recipe is abnormally terminated when the error processing step is performed in the step (c).
